(19) United States
(12) Patent Application Publication
(10) Pub. No.: US 2006/0077032 A1
(43) Pub. Date: Apr. 13, 2006

(54) Magnetoresistive element

(76) Inventors: Shogo Momose, Nagano (JP); Masao Takemura, Nagano (JP); Fusayoshi Aruga, Nagano (JP); Naoyuki Noguchi, Nagano (JP); Teruhiko Otaki, Nagano (JP)

Correspondence Address: CANTOR COLBURN, LLP, 55 GRIFFIN ROAD SOUTH, BLOOMFIELD, CT, 06002, US

(21) Appl. No.: 11/226,158

(22) Filed: Sep. 14, 2005

(30) Foreign Application Priority Data
Sep. 17, 2004 (JP) 2004-271557

(51) Int. Cl. H01L 43/08; G01B 7/30; H01L 43/02; H01L 43/00; G01B 7/14; H01L 43/10; G01R 33/06; H01L 43/04

(52) U.S. Cl. 338/32 R; 324/207.21

(57) ABSTRACT

A magnetoresistive element may include an A-phase magnetoresistive pattern which outputs a signal, a B-phase magnetoresistive pattern which outputs another signal whose phase is different by 90° from a phase of the signal outputted from the A-phase magnetoresistive pattern, a first substrate on which the A-phase magnetoresistive pattern is formed, and a second substrate on which the B-phase magnetoresistive pattern is formed. At least one of the first and the second substrates may include a transparent substrate.

### CROSS REFERENCE TO RELATED APPLICATION

The present invention claims priority under 35 U.S.C. §119 to Japanese Application No. 2004-271557 filed Sep. 17, 2004, which is incorporated herein by reference.

### FIELD OF THE INVENTION

An embodiment of the present invention may relate to a magnetoresistive element for detecting the moving amount, the position, the moving speed or the like of a movable detection object to be detected.

### BACKGROUND OF THE INVENTION

A magnetoresistive element has been used as a sensor for detecting the moving amount of a movable detection object to be detected. For example, the magnetoresistive element is utilized such that a multipolar magnetized layer magnetized with a prescribed pitch (magnetic scale) is formed in a movable detection object to be detected and the magnetoresistive element is disposed so as to face the multipolar magnetized layer. The magnetoresistive element is provided with four magnetic resistors formed in a thin film at a pitch narrower than the pitch of the ultipolar magnetization. A moving amount is detected by detecting the resistance values of magnetic resistors that are changed due to the movement of the movable detection object.

An output signal from a magnetoresistive element is commonly formed of a fundamental wave component and harmonic components which are superposed in the fundamental wave component. The harmonic components can be eliminated by devising the arrangement of the plurality of magnetic resistors to obtain a smooth output signal such as a fundamental wave component and thus a discrimination accuracy can be enhanced (see, for example, Japanese Patent No. 2,529,960 (FIG. 2)).

According to the magnetoresistive element described in the prior art, the magnetoresistive element which is disposed so as to face a multipolar magnetized layer is constructed such that a plurality of magnetic resistors formed in a thin film are arranged with prescribed intervals therebetween to be capable of canceling the harmonic components caused by the saturation of the change of a magnetic resistance with opposite phases. As a result, the output signal in a smooth sine wave can be obtained.

On the other hand, when the magnetic field of a magnetic scale is detected by a plurality of magnetic resistors formed in a thin film, all the magnetic resistors are commonly disposed on one piece of glass substrate. For example, all the plurality of magnetic resistors formed in a thin film are mounted on a magnetoresistive element mounting part which is mounted along the positioning guide of a holder (see Japanese Patent Laid-Open No. Hei 10-253729 (FIG. 1)).

However, when a plurality of magnetic resistors formed in a thin film are disposed on one piece of a glass substrate to cancel the harmonic components of an output signal to improve the discrimination accuracy, the distances between the respective magnetic resistors become very narrow and thus it is difficult that the respective magnetic resistors are disposed at desired positions.

Especially, in a magnetoresistive element provided with an A-phase magnetoresistive pattern and a B-phase magnetoresistive pattern which output two signals whose phases are different by 90° from each other, when each of the magnetoresistive pattern is provided with a plurality of magnetic resistors formed in a thin film in order to improve the discrimination accuracy, the distances between the respective magnetic resistors are further required to be narrow. Therefore, an extremely high degree of accuracy is required in a producing process and the degree of freedom in layout of the magnetic resistors formed in a thin film is remarkably reduced.

### SUMMARY OF THE INVENTION

In view of the problems described above, the present invention may advantageously provide a magnetoresistive element which does not require an extremely high degree of accuracy in a producing process even when a plurality of magnetic resistors formed in a thin film is used and is capable of improving the degree of freedom of the layout of the magnetic resistors formed in a thin film.

Thus, according to the present invention, there may be provided a magnetoresistive element including an A-phase magnetoresistive pattern which outputs a signal, a B-phase magnetoresistive pattern which outputs another signal whose phase is different by 90° from that of the signal outputted from the A-phase magnetoresistive pattern, a first substrate on which the A-phase magnetoresistive pattern is formed, and a second substrate on which the B-phase magnetoresistive pattern is formed. At least one of the first and the second substrates is a transparent substrate.

In accordance with an embodiment of the present invention, the A-phase magnetoresistive pattern and the B-phase magnetoresistive pattern are respectively formed on separate substrates (the first substrate and the second substrate) and these two separate substrates are disposed so as to be faced each other to form one completed magnetoresistive pattern. Therefore, even when a plurality of magnetic resistors formed in a thin film is used in order to cancel the harmonic components and improve the detection accuracy, intervals between the magnetic resistors formed in a thin film formed on one piece of substrate are not necessary to be extremely narrow. Accordingly, even when a plurality of magnetic resistors formed in a thin film is used, an extremely high degree of accuracy is not required in a producing process and the degree of freedom for the layout of magnetic resistors is high. Further, in an embodiment of the present invention, since at least one of the first and the second substrates is a transparent substrate, the position of the other substrate can be confirmed through the transparent substrate. Therefore, the first substrate and the second substrate can be oppositely faced with a high degree of positional accuracy.

In accordance with an embodiment of the present invention, the first and the second substrates are preferably disposed such that the surfaces on which the A-phase and the B-phase magnetoresistive patterns are formed oppositely face each other. In this case, all of the A-phase and the B-phase magnetoresistive patterns formed on the first substrate and the second substrate are preferably sandwiched by the first substrate and the second substrate. In addition, it is preferable that each of the first substrate and the second substrate protrudes from the edge part of the other substrate and respective protruding parts are to be connected to a flexible circuit board for outputting a signal.

In accordance with an embodiment of the present invention, it is preferable that the first substrate and the second substrate are adhesively joined to each other with a photosetting adhesive. In accordance with an embodiment of the present invention, the photosetting adhesive is, for example, a UV-curing adhesive. In accordance with an embodiment of the present invention, since at least one of the first and the second substrates is a transparent substrate, the first substrate and the second substrate can be affixed to each other by irradiating a UV light beam through the transparent substrate side in the state that the first substrate and the second substrate are oppositely faced with the photosetting adhesive interposed therebetween.

In accordance with an embodiment of the present invention, it is preferable that one of the first substrate and the second substrate is a transparent substrate and the other is a glazed ceramic substrate. According to the construction described above, the strength can be enhanced in comparison with the case that both the first substrate and the second substrate are made of a glass substrate. Further, it is preferable that the glazed ceramic substrate is disposed on a side which is to be faced to a magnetic scale that is to be detected by the A-phase and the B-phase magnetoresistive patterns and the thickness of the ceramic glazed substrate is thinner than that of the transparent substrate.

According to an embodiment of the present invention, in a magnetoresistive element provided with an A-phase magnetoresistive pattern and a B-phase magnetoresistive pattern which output two signals whose phases are different by 90° from each other, the A-phase magnetoresistive pattern and the B-phase magnetoresistive pattern are respectively formed on separate substrates (the first substrate and the second substrate) and these two separate substrates are disposed so as to be faced each other to form one completed magnetoresistive pattern. Therefore, even when a plurality of magnetic resistors formed in a thin film is used in order to cancel the harmonic components and improve the detection accuracy, intervals between the magnetic resistors formed in a thin film formed on one piece of substrate are not necessary to be extremely narrow. Accordingly, even when a plurality of magnetic resistors formed in a thin film is used, an extremely high degree of accuracy is not required in a producing process and the degree of freedom for the layout of magnetic resistors is high. Further, in an embodiment of the present invention, since at least one of the first and the second substrates is a transparent substrate, the position of the other substrate can be confirmed through the transparent substrate. Therefore, the first substrate and the second substrate can be oppositely faced with a high degree of positional accuracy.

Other features and advantages of the invention will be apparent from the following detailed description, taken in conjunction with the accompanying drawings that illustrate, by way of example, various features of embodiments of the invention.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1(a) is an explanatory view showing the positional relationship between a head provided with a magnetoresistive element in accordance with an embodiment of the present invention and a magnetic scale, FIG. 1(b) is an explanatory view showing a magnetic linear encoder in which a magnetoresistive element in accordance with an embodiment of the present invention is used, and FIG. 1(c) is an explanatory view showing a rotary encoder in which a magnetoresistive element in accordance with an embodiment of the present invention is used.

FIGS. 2(a) through 2(c) are explanatory views showing a producing method for a magnetoresistive element in accordance with an embodiment of the present invention.

FIG. 3 is a graph showing a time sequential sensor output of a magnetoresistive element in accordance with an embodiment of the present invention.

FIGS. 4(a) through 4(f) are explanatory views showing a producing method for a magnetoresistive element in accordance with an embodiment of the present invention from a large-sized substrate.

FIG. 5 is an explanatory view showing an example in which a magnetoresistive element in accordance with an embodiment of the present invention is used in a magnetic sensor device (magnetic linear encoder) as shown in FIG. 1(b).

FIGS. 6(a) and 6(b) are explanatory views showing the head used in the magnetic sensor device shown in FIG. 5 which is viewed from the side of the bottom face that is provided with a magnetism-sensitive surface.

FIG. 7(a) is an explanatory view showing the positional relationship between the head and the magnetic scale in the magnetic sensor device shown in FIG. 5 and FIG. 7(b) is a right side view showing the head.

FIG. 8(a) is an explanatory view showing a magnetoresistive element mounted on the head of the magnetic sensor device shown in FIG. 5, FIG. 8(b) is an explanatory view showing the state where the magnetoresistive element is connected to a circuit board, FIG. 8(c) is the block diagram of a circuit mounted on the head of a magnetic sensor device in accordance with an embodiment of the present invention, and FIG. 8(d) is the block diagram of a circuit that is mounted on a conventional head.

FIGS. 9(a) and 9(b) are explanatory views showing the internal structure of a sensor holder which is used in the head of the magnetic sensor device shown in FIG. 5.

FIG. 10(a) is an explanatory view showing a connecting structure between the head and a cable which are used in the magnetic sensor device shown in FIG. 5 and FIG. 10(b) is a perspective view showing a sleeve used in the connecting structure shown in FIG. 10(a).

FIG. 11(a) is a sectional view showing a portion around a cable insert hole which is cut at positions corresponding to the line X1-X1′ in FIG. 7(a) and FIG. 10(b), and FIG. 11(b) is a sectional view showing a portion around the cable insert hole which is cut at positions corresponding to the line Z1-Z1′ in FIG. 7(b) and FIG. 10(b).

FIG. 12(a) is a longitudinal sectional view showing a magnetic scale which is used in the magnetic sensor device shown in FIG. 5 and FIG. 12(b) is an explanatory view showing its internal structure.

### DETAILED DESCRIPTION OF THE PREFERRED EMBODIMENTS

An embodiment of the present invention will be described below with reference to the accompanying drawings.

[Structure of Magnetoresistive Element]

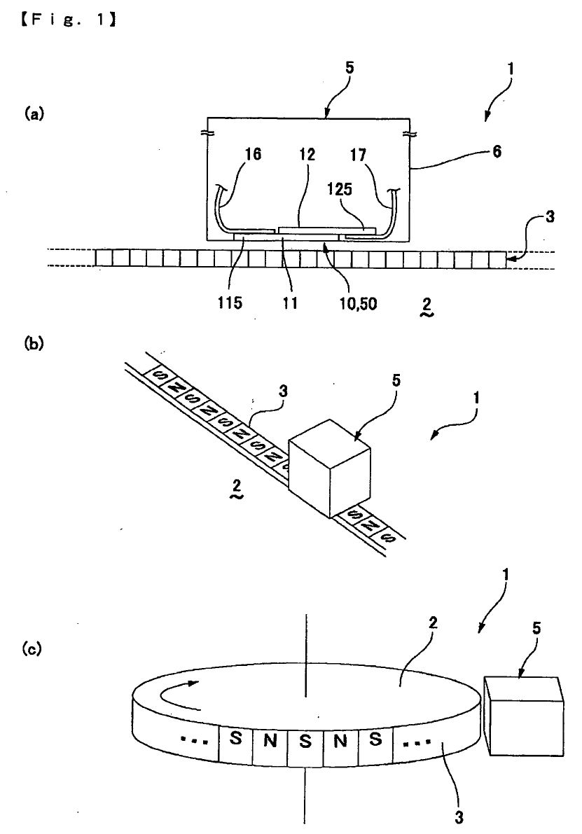

FIG. 1(a) is an explanatory view showing the positional relationship between a head provided with a magnetoresistive element and a magnetic scale to which the present invention is applied, FIG. 1(b) is an explanatory view showing a magnetic linear encoder in which a magnetoresistive element to which the present invention is applied is used, and FIG. 1(c) is an explanatory view showing a rotary encoder in which a magnetoresistive element to which the present invention is applied is used.

In FIG. 1(a), a magnetoresistive element 10 to which the present invention is applied constructs a magnetism-sensitive surface 50 of a head 5 in a magnetic sensor device 1 for measuring or detecting the moving distance of a table of a machine tool or a mounting device, the rotational position of a robot or the like, and the rotating speed or the like of a motor device. The magnetoresistive element 10 is mounted in a sensor holder 6 of the head 5. The magnetism-sensitive surface 50 of the head 5 is oppositely disposed to a magnetic scale 3 and the magnetic scale 3 is mounted on a movable body 2. The magnetoresistive element 10 is provided with an A-phase magnetoresistive pattern and a B-phase magnetoresistive pattern which output two signals whose phases are different by 90° from each other as described below in detail.

In an embodiment of the present invention, the magnetoresistive element 10 is provided with a first magnetoresistive element circuit board 11 on which the A-phase magnetoresistive pattern is formed and a second magnetoresistive element circuit board 12 on which the B-phase magnetoresistive pattern is formed. The first and the second magnetoresistive element circuit boards 11, 12 are adhered such that the surfaces formed with the magnetoresistive pattern face each other.

Both the first magnetoresistive element circuit board 11 and the second magnetoresistive element circuit board 12 are extended from the edge part of the other circuit board. Flexible circuit boards 16, 17 are connected to a protruding portion 115 of the first magnetoresistive element circuit board 11 and to a protruding portion 125 of the second magnetoresistive element circuit board 12 by a method such as attaching by pressure. The connecting portions of the flexible circuit boards 16, 17 are coated with resin (not shown in the drawings).

The head 5 constructed as described above is disposed, for example, so as to face the magnetic scale 3 extended on a moving table (movable body 2) in a linear manner in the magnetic sensor device 1 (magnetic linear encoder) shown in FIG. 1(b) to detect the position or the like of the moving table. Alternatively, the head 5 is disposed so as to face the magnetic scale 3 which is disposed on the outer peripheral face of a rotatable drum (movable body 2) in the magnetic sensor device 1 (magnetic rotary encoder) shown in FIG. 1(c) to detect the rotating position or the rotating speed of the rotatable drum. In any case, an N-pole and an S-pole are alternately arranged in the magnetic scale 3 with a prescribed pitch.

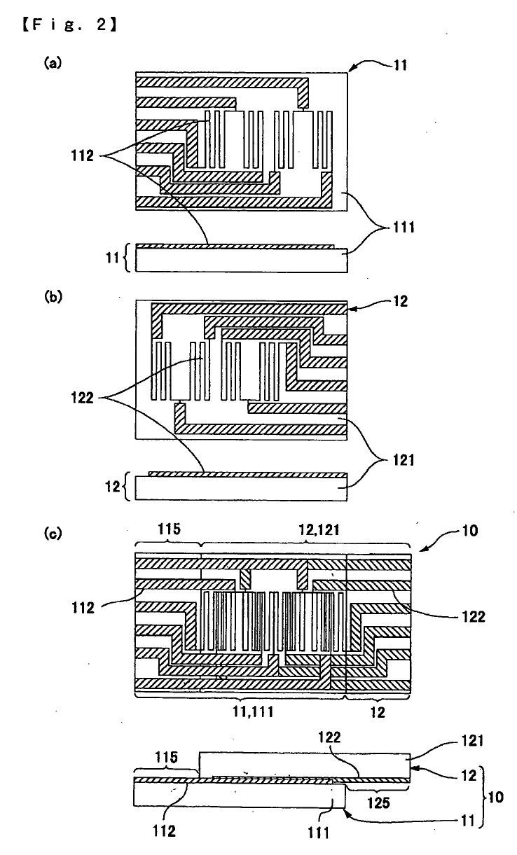

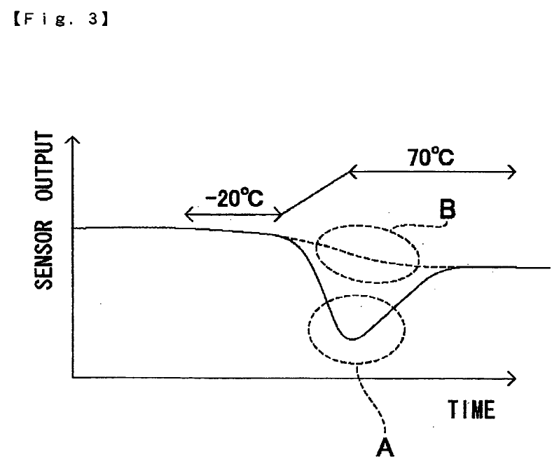

The production method, the detailed structure and the characteristic of the magnetoresistive element 10 in accordance with an embodiment of the present invention will be described below in detail with reference to FIGS. 2(a) through 2(c) and FIG. 3. FIGS. 2(a) through 2(c) are explanatory views showing the producing method for the magnetoresistive element 10 in accordance with an embodiment of the present invention. FIG. 3 is a graph showing a time sequential sensor output of the magnetoresistive element 10 to which the present invention is applied.

In an embodiment of the present invention, as shown in FIGS. 2(a) and 2(b), a first substrate 111 for constructing the first magnetoresistive element circuit board 11 which is positioned on a lower side and a second substrate 121 for constructing the second magnetoresistive element circuit board 12 which is positioned on an upper side are prepared.

In an embodiment of the present invention, a glazed ceramic substrate is prepared for the first substrate 111 and a glass substrate (transparent substrate) is prepared for the second substrate 121. The glazed ceramic substrate is constructed such that a glass layer is formed on the surface of a ceramic substrate such as an alumina substrate made of an oxide or a nitride. In an embodiment of the present invention, since the first magnetoresistive element circuit board 11 is disposed on the magnetic scale 3 side, a thinner substrate is used as the first substrate 111 than the thickness of the second substrate 121. For example, the thickness of the first substrate 111 is 0.3 mm and the thickness of the second substrate 121 is 0.7 mm.

Next, as shown in FIG. 2(a), a magnetic material film made of ferromagnetic material NiFe or the like is formed on the surface of the first substrate 111 by a sputtering method or the like, and then the magnetic material film is patterned by using a photo-lithography technique to form the A-phase magnetoresistive pattern 112. In this case, alignment marks (not shown) are simultaneously formed on the first substrate 111 by using the magnetic material film. Next, a protective layer is formed on the surface of the A-phase magnetoresistive pattern 112 to complete the first magnetoresistive element circuit board 11.

Similarly, as shown in FIG. 2(b), a magnetic material film made of ferromagnetic material NiFe or the like is formed on the surface of the second substrate 121 by a sputtering method or the like, and then the magnetic material film is patterned by using a photo-lithography technique to form the B-phase magnetoresistive pattern 122. In this case, alignment marks are also simultaneously formed on the second substrate 121 by using the magnetic material film. Next, a protective layer is formed on the surface of the B-phase magnetoresistive pattern 122 to complete the second magnetoresistive element circuit board 12.

Both the magnetic resistors formed in a thin film in the A-phase magnetoresistive pattern 112 and the magnetic resistors formed in a thin film in the B-phase magnetoresistive pattern 122 are respectively constructed in a differential configuration to improve their temperature characteristics. Further, both the A-phase magnetoresistive pattern 112 and the B-phase magnetoresistive pattern 122 are respectively provided with a plurality of magnetic resistors formed in a thin film to eliminate the harmonic components superposed in the fundamental wave component of an output signal.

Next, after a UV-curing adhesive as a photosetting adhesive is coated on the first magnetoresistive element circuit board 11 or the second magnetoresistive element circuit board 12, the first magnetoresistive element circuit board 11 and the second magnetoresistive element circuit board 12 are joined with the UV-curing adhesive held therebetween as shown in FIG. 2(c). Alternatively, after the first magnetoresistive element circuit board 11 and the second magnetoresistive element circuit board 12 are disposed in an oppositely faced manner, the UV-curing adhesive is coated to their edge portions. In this case, since the second substrate 121 is a transparent glass substrate, the alignment between the first magnetoresistive element circuit board 11 and the second magnetoresistive element circuit board 12 is performed while observing the alignment marks of the first magnetoresistive element circuit board 11 and the alignment marks of the second magnetoresistive element circuit board 12 through the second substrate 121. Alternatively, when the alignment marks are not formed on the first magnetoresistive element circuit board 11 and the second magnetoresistive element circuit board 12, the alignment between the first magnetoresistive element circuit board 11 and the second magnetoresistive element circuit board 12 may be performed while observing the A-phase magnetoresistive pattern 112 and the B-phase magnetoresistive pattern 122.

Next, a UV light is irradiated through the transparent second substrate 121 side to harden the UV-curing adhesive and the first magnetoresistive element circuit board 11 and the second magnetoresistive element circuit board 12 are adhered to each other.

When the first magnetoresistive element circuit board 11 and the second magnetoresistive element circuit board 12 are adhered to each other, respective one parts of the first magnetoresistive element circuit board 11 and the second magnetoresistive element circuit board 12 are protruded from the edge portion of the other circuit board. Therefore, even when the magnetoresistive element 10 is constructed by adhering two magnetoresistive element circuit boards 11, 12 together, flexible circuit boards 16, 17 can be connected to the protruding parts 115, 125 of the respective magnetoresistive element circuit boards 11, 12 by a method such as attaching by pressure as shown in FIG. 1(a). In this manner, the magnetoresistive element 10 is produced.

In the magnetoresistive element 10 constructed as described above, the A-phase magnetoresistive pattern 112 and the B-phase magnetoresistive pattern 122 are formed on the respective substrates (first substrate 111 and second substrate 121) and the required magnetoresistive pattern is constructed by the two substrates which are oppositely faced each other. Therefore, even when a plurality of magnetic resistors formed in a thin film is used in order to cancel the harmonic components and improve the detection accuracy, intervals between the magnetic resistors formed in a thin film formed on one piece of substrate are not necessary to be extremely narrow. Accordingly, even when a plurality of magnetic resistors formed in a thin film is used, an extremely high degree of accuracy is not required in a producing process and the degree of freedom for the layout of magnetic resistors is high.

Further, in an embodiment of the present invention, since the second substrate 121 is made of a transparent substrate, the position of the first substrate 111 can be confirmed through the second substrate 121 (transparent substrate). Therefore, the first magnetoresistive element circuit board 11 and the second magnetoresistive element circuit board 12 can be oppositely faced with a high degree of positional accuracy.

In addition, since the second substrate 121 is made of a transparent substrate, a UV light can be irradiated between the substrates through the second substrate 121 (transparent substrate). Therefore, the first magnetoresistive element circuit board 11 and the second magnetoresistive element circuit board 12 can be adhered to each other with a UV-curing adhesive. Accordingly, different from the case that the first magnetoresistive element circuit board 11 and the second magnetoresistive element circuit board 12 are adhered to each other with a thermosetting resin, a thermal stress is not produced in the first magnetoresistive element circuit board 11 and the second magnetoresistive element circuit board 12 and, furthermore, the first magnetoresistive element circuit board 11 and the second magnetoresistive element circuit board 12 are not required to be carried through the heating apparatus. Consequently, according to an embodiment of the present invention, the magnetoresistive element 10 with a high degree of reliability can be efficiently produced.

Further, in an embodiment of the present invention, since the first magnetoresistive element circuit board 11 is disposed on the magnetic scale 3 side, the thickness of the first substrate 111 is set to be thinner than that of the second substrate 121. Therefore, the gap space between the magnetoresistive pattern and the magnetic scale 2 can be smaller and thus a high degree of sensitivity can be obtained. In addition, although the first substrate 111 is thin, the first substrate 111 is made of a glazed ceramic substrate and thus a sufficient strength can be attained.

Moreover, in an embodiment of the present invention, the respective one parts of the first magnetoresistive element circuit board 11 and the second magnetoresistive element circuit board 12 are respectively protruded from the edge part of the other circuit board. Therefore, even when the magnetoresistive element 10 is constructed by affixing the magnetoresistive element circuit boards 11, 12 together, the flexible circuit boards 16, 17 can be connected to the respective protruding parts 115, 125 of the magnetoresistive element circuit boards 11, 12 and thus the signals from the respective magnetoresistive element circuit boards 11, 12 can be inputted to the flexible circuit boards 16, 17.

Further, the A-phase magnetoresistive pattern 112 and the B-phase magnetoresistive pattern 122 are sandwiched by the first substrate 111 and the second substrate 121 and thus the magnetoresistive element is resistant to impacts from the outside. Also, since the A-phase magnetoresistive pattern 112 and the B-phase magnetoresistive pattern 122 are sandwiched by the first substrate 111 and the second substrate 121, the A-phase magnetoresistive pattern 112 and the B-phase magnetoresistive pattern 122 do not react sensitively to a rapid change of the external temperature and thus a stable temperature characteristic can be obtained as shown in FIG. 3.

As shown in FIG. 3, in a conventional magnetoresistive element 10 which is constructed such that a magnetoresistive pattern is formed on one piece of substrate, an overshoot is occurred like the “A” portion in FIG. 3 when the temperature is changed, for example, from −20° C. to 70° C. even in the thermostatic chamber. This is because a differential output is commonly obtained to improve the temperature characteristic of the magnetic resistors formed in a thin film but, when the temperature is rapidly changed, a uniform temperature environment is not obtained. However, in the magnetoresistive element 10 to which the present invention is applied, the A-phase magnetoresistive pattern 112 and the B-phase magnetoresistive pattern 122 are sandwiched by the first substrate 111 and the second substrate 121. Therefore, the overshoot does not occur as shown in the “B” portion in FIG. 3 and thus a stable temperature characteristic can be obtained.

In FIG. 2(c), the A-phase magnetoresistive pattern 112 and the B-phase magnetoresistive pattern 122 are in contact with each other without a gap space but they may be disposed so as to have some gap space between them.

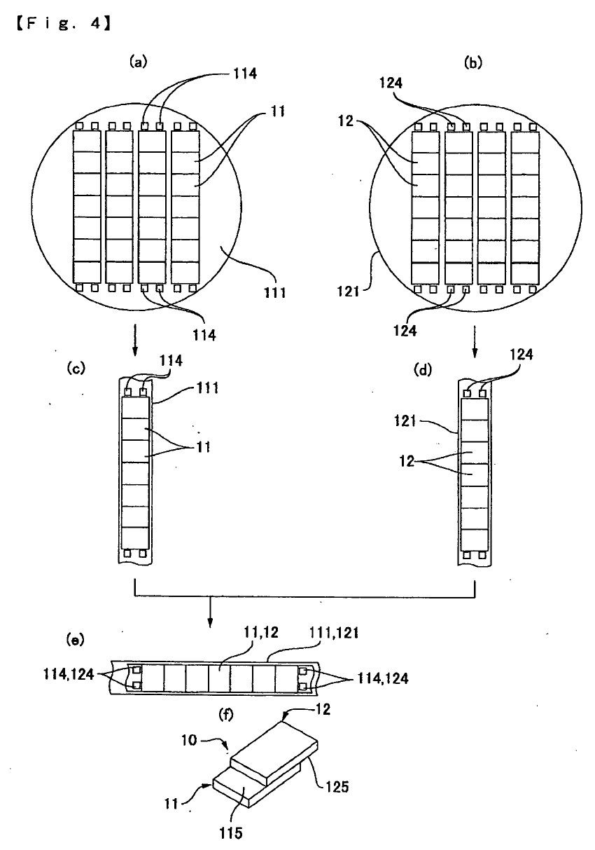

FIGS. 4(a) through 4(f) are explanatory views showing a producing method for a magnetoresistive element in accordance with an embodiment of the present invention from a large-sized substrate.

As a producing method for the magnetoresistive element 10 in accordance with an embodiment of the present invention, the magnetoresistive patterns 112, 122 are respectively formed on the first substrate 111 and the second substrate 121 in a single-unit size to produce the first magnetoresistive element circuit board 11 and the second magnetoresistive element circuit board 12 and, after that, the first magnetoresistive element circuit board 11 and the second magnetoresistive element circuit board 12 may be joined to each other. However, as described below, a plurality of the magnetoresistive patterns 112, 122 may be formed on a large-sized substrate so that a plurality of the first magnetoresistive element circuit boards 11 and a plurality of the second magnetoresistive element circuit boards 12 can be cut out in a single-unit size.

First, as shown in FIG. 4(a), a first large-scale substrate 111 is prepared which has a size from which a large number of the first magnetoresistive element circuit boards 11 is capable of being cut out and then the A-phase magnetoresistive patterns (not shown), the alignment marks 114 and the like are formed on the surface of the first large-scale substrate 111 in a region where the first magnetoresistive element circuit boards 11 are cut out. The first large-scale substrate 111 is a glazed ceramic substrate whose thickness is, for example, 0.3 mm.

Further, as shown in FIG. 4(b), a second large-scale substrate 121 is prepared which has a size from which a large number of the second magnetoresistive element circuit boards 12 is capable of being cut out and then the B-phase magnetoresistive patterns (not shown), the alignment marks 124 and the like are formed on the surface of the second large-scale substrate 121 in a region where the second magnetoresistive element circuit boards 12 are cut out. The second large-scale substrate 121 is a glass substrate whose thickness is, for example, 0.3 mm.

Next, as shown in FIGS. 4(c) and 4(d), the first large-scale substrate 111 and the second large-scale substrate 121 are respectively cut in a strip shape.

Next, as shown in FIG. 4(e), after a UV-curing adhesive as a photosetting adhesive is coated on the first substrate 111 or the second substrate 121 in a strip shape, the first strip-shaped substrate 111 and the second strip-shaped substrate 121 are adhered to each other with the UV-curing adhesive. Alternatively, after the first strip-shaped substrate 111 and the second strip-shaped substrate 121 are disposed in an oppositely faced manner, the UV-curing adhesive is coated to their edge portions. In this case, since the second substrate 121 is a transparent glass substrate, the alignment between the first magnetoresistive element circuit board 11 and the second magnetoresistive element circuit board 12 is performed while observing alignment marks 114 of the first magnetoresistive element circuit board 11 and alignment marks 124 of the second magnetoresistive element circuit board 12 through the second substrate 121. Alternatively, when the alignment marks 114, 124 are not formed on the first magnetoresistive element circuit board 11 and the second magnetoresistive element circuit board 12, the alignment between the first magnetoresistive element circuit board 11 and the second magnetoresistive element circuit board 12 may be performed while observing the A-phase magnetoresistive pattern and the B-phase magnetoresistive pattern.

Next, a UV light is irradiated through the transparent second substrate 121 side to harden the UV-curing adhesive and the first magnetoresistive element circuit board 11 and the second magnetoresistive element circuit board 12 are fixed to each other.

After that, the first strip-shaped substrate 111 and the second strip-shaped substrate 121 are cut at specified positions. As a result, a magnetoresistive element 10 is obtained in which the first magnetoresistive element circuit board 11 and the second magnetoresistive element circuit board 12 are joined such that the respective circuit boards 11, 12 are provided with the protruding parts 115, 125 as shown in FIG. 4(f). After that, the flexible circuit boards 16, 17 are connected to the protruding parts 115, 125 of the respective magnetoresistive element circuit boards 11, 12 by a method such as attaching by pressure as shown in FIG. 1(a).

In the case that the first substrate 111 and the second substrate 121 are completely overlapped when the first strip-shaped substrate 111 and the second strip-shaped substrate 121 are adhered to each other as shown in FIG. 4(e), the protruding parts 115, 125 may be formed when the first substrate 111 and the second substrate 121 are cut. Alternatively, as shown in FIG. 4(e), when the first strip-shaped substrate 111 and the second strip-shaped substrate 121 are adhered to each other, the respective protruding parts 115, 125 may be formed by the first substrate 111 and the second substrate 121 being shifted to each other.

[Example of Magnetic Sensor Device 1]

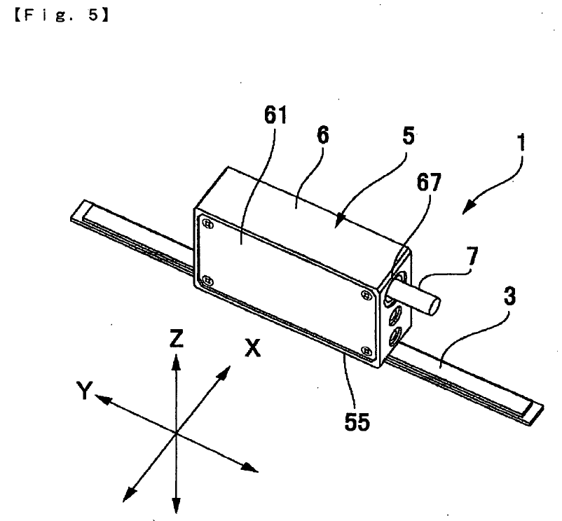

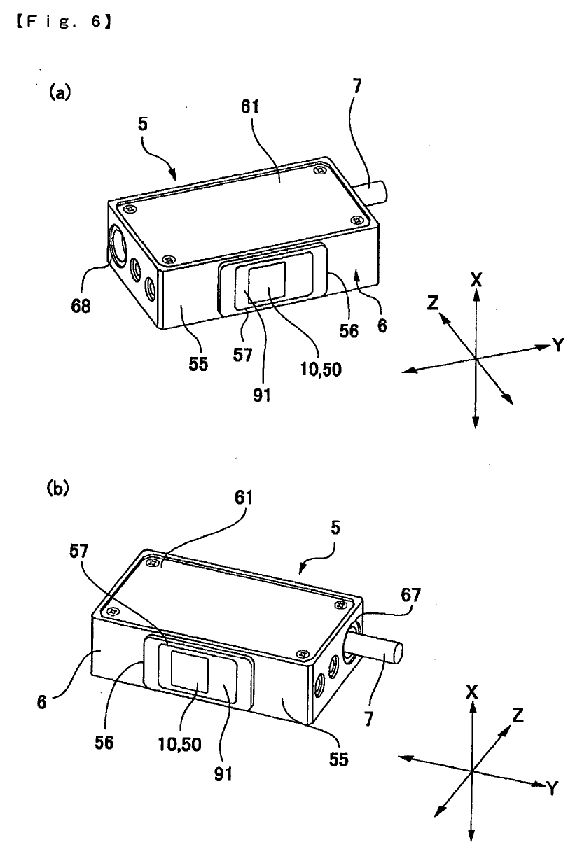

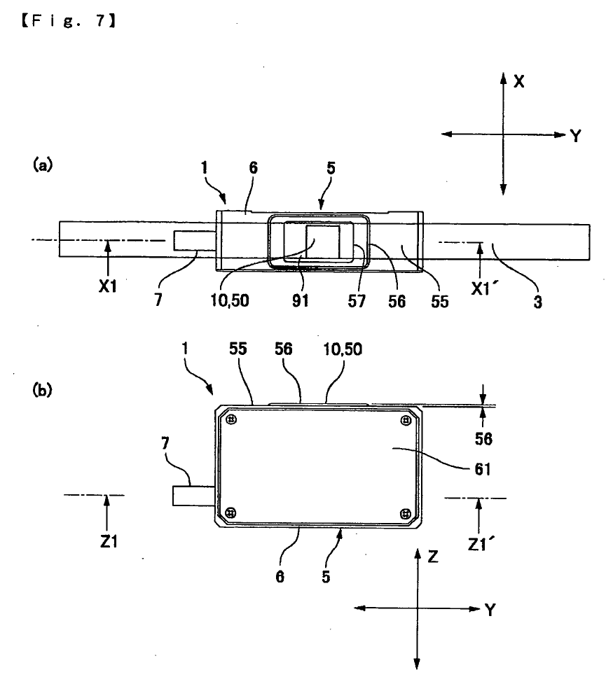

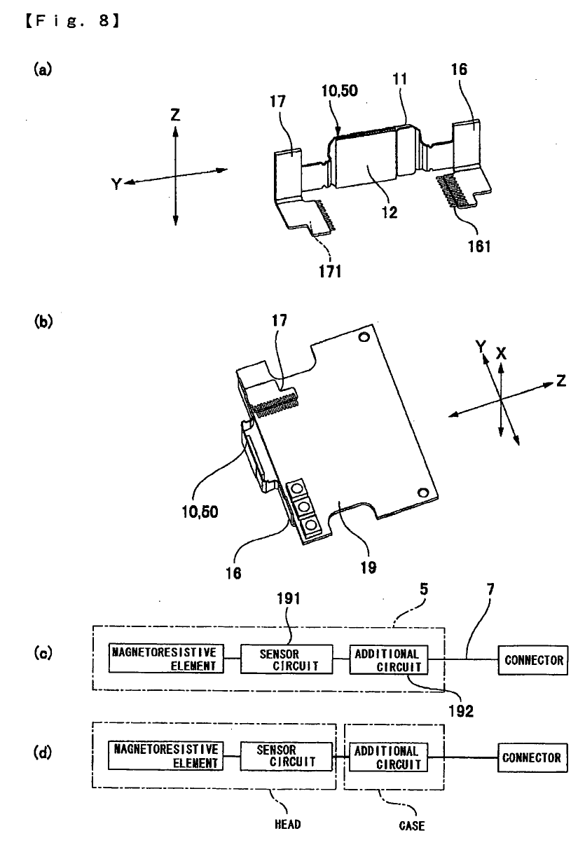

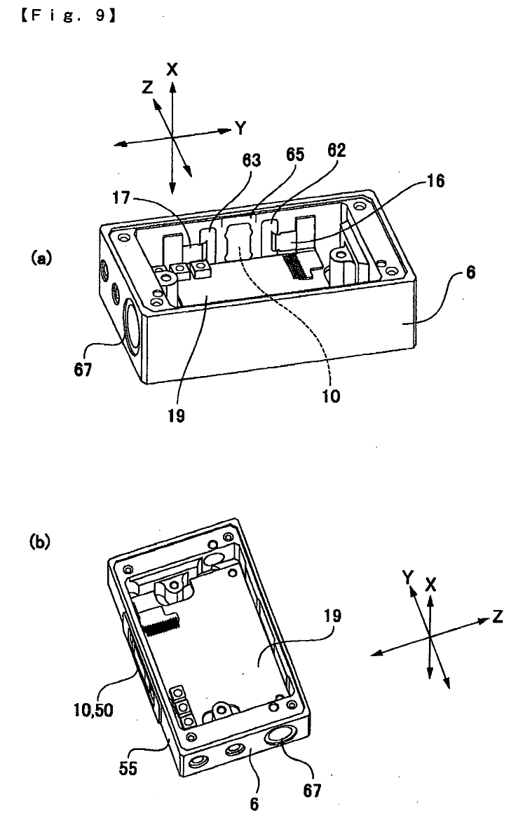

FIG. 5 is an explanatory view showing the case in which the magnetoresistive element 10 in accordance with an embodiment of the present invention is used in the magnetic sensor device 1 (magnetic linear encoder) as shown in FIG. 1(b). FIGS. 6(a) and 6(b) are explanatory views showing the head 5 used in the magnetic sensor device 1 which is viewed from the side of the bottom face provided with a magnetism-sensitive surface shown in FIG. 5. FIG. 7(a) is an explanatory view showing the positional relationship between the head 5 and the magnetic scale 3 in the magnetic sensor device 1 shown in FIG. 5 and FIG. 7(b) is a right side view showing the head 5. FIG. 8(a) is an explanatory view showing a magnetoresistive element 10 which is mounted on the head 5 of the magnetic sensor device 1 in an embodiment of the present invention, FIG. 8(b) is an explanatory view showing the state where the magnetoresistive element 10 is connected to a circuit board, FIG. 8(c) is the block diagram of a circuit which is mounted on the head 5 of the magnetic sensor device 1 in accordance with an embodiment of the present invention, and FIG. 8(d) is the block diagram of a circuit which is mounted on a conventional head 5. FIGS. 9(a) and 9(b) are explanatory views showing the internal structure of a sensor holder which is used in the head 5 of the magnetic sensor device 1 in accordance with an embodiment of the present invention. In the following description, the width direction of the magnetic scale 3 is set to be an X-direction, the length direction of the magnetic scale 3 is set to be a Y-direction, and its height direction is set to be a Z-direction as shown in FIG. 5.

In FIG. 5, FIGS. 6(a) and 6(b) and FIGS. 7(a) and 7(b), the magnetic sensor device 1 in accordance with an embodiment of the present invention includes the head 5 in which its magnetism-sensitive surface 50 is formed with the magnetoresistive element 10 in accordance with an embodiment of the present invention and the magnetic scale 3 which faces the magnetism-sensitive surface 50 of the head 5.

The head 5 includes a sensor holder 6 formed of a generally rectangular parallelepiped aluminum die cast, a rectangular cover 61 which covers the right side opening part of the sensor holder 6, and a cable 7 which is drawn out from the inside of the sensor holder 6. A cable insert hole 67 is formed in the back face of the sensor holder 6 and another hole which can be utilized as the cable insert hole 67 is also formed in its front face. Therefore, the common sensor holder 6 can be used even when the cable 7 is drawn out from either side of the sensor holder 6.

An opening part 57 is formed in the bottom face 55 of the sensor holder 6 which faces the magnetic scale 3 and a magnetism-sensitive part 50 is constructed by disposing the magnetoresistive element 10 at the opening part 57. A flat reference surface 56 is formed on the bottom face 55 of the sensor holder 6 such that the center region of the bottom face 55 where the magnetism-sensitive surface 50 is formed is protruded from its peripheral portion by 0.2 mm-1.0 mm. The area of the reference surface 56 is about half of that of the entire bottom face 55.

The magnetoresistive element 10 is disposed within the sensor holder 6 in the state where a pair of the flexible circuit boards 16, 17 are connected by a method such as attaching by pressure as shown in FIG. 8(a). A pair of the flexible circuit boards 16, 17 are extended from the magnetoresistive element 10 toward opposite sides. Further, in the state that a pair of the flexible circuit boards 16, 17 are connected to the magnetoresistive element 10, connection terminals 161, 171 to a circuit board 19 are directed in opposite directions. Therefore, the flexible circuit board 16 is connected to the front face side of the circuit board 19 and the flexible circuit board 17 is connected to the rear face side of the circuit board 19 as shown in FIG. 8(b).

As shown in FIGS. 9(a) and 9(b), an element support part 65 formed in a frame-like manner is formed on an inner side of the opening part 57 in the sensor holder 6 so as to face the opening part 57 in order to dispose the circuit board 19 and the magnetoresistive element 10 in the sensor holder 6. Aperture parts 62, 63 for drawing the flexible circuit boards 16, 17 inside are formed on both sides of the element support part 65.

Therefore, in the case that the head 5 is assembled, first, the magnetoresistive element 10 to which a pair of the flexible circuit boards 16, 17 are connected are disposed from outside such that the magnetoresistive element 10 is exposed to the outside through the opening part 57. Further, a pair of the flexible circuit boards 16, 17 is drawn into the sensor holder 6 from the aperture parts 62, 63. Next, the rear face side of the magnetoresistive element 10 is fixed to the element support part 65 with an adhesive and the periphery in the opening part 57 of the magnetoresistive element 10 is filled up with an adhesive 91 to fix the magnetoresistive element 10 to the sensor holder 6. In this state, the outer side face of the magnetoresistive element 10 is exposed in the opening part 57 and forms the same flat surface with the reference surface 56 of the sensor holder 6. Next, the midway portions of the flexible circuit boards 16, 17 are bent in a perpendicular direction and then the flexible circuit board 16 is connected to the front face of the circuit board 19 and the flexible circuit board 17 is connected to the rear face of the circuit board 19. After that, when the circuit board 19 is disposed so as to be along the left side inner wall of the sensor holder 6, the magnetoresistive element 10 and the circuit board 19 are mounted within the sensor holder 6 in the state that they are disposed to be perpendicular to each other. Next, the cable 7 is inserted into the sensor holder 6 through the cable insert hole 67 and connected to the circuit board 19 and, after that, a cover 61 is fitted to the sensor holder 6 so as to cover its opening part. In this way, the head 5 is completed.

In an embodiment of the present invention, as shown in FIG. 8(c), a sensor circuit 191 and an additional circuit 192 by which a temperature correction or the like is performed on a signal outputted from the sensor circuit 191 are constructed on the circuit board 19. The additional circuit 192 is conventionally constructed within a different case from the head as shown in FIG. 8(d). However, in an embodiment of the present invention, the additional circuit 192 is constructed on the circuit board 19 so as to be incorporated within the head 5. Therefore, according to an embodiment of the present invention, since the sensor circuit 191 and the additional circuit 192 are connected to each other on the circuit board 19, the length where an analog signal is transmitted is short and thus the occurrence such as the intrusion of noise or the distortion of waveform can be prevented.

When both the sensor circuit 191 and the additional circuit 192 are constructed on the circuit board 19, the circuit board 19 becomes larger than the conventional circuit board and thus the head 5 itself may also become larger than the conventional head. However, in accordance with an embodiment of the present invention, the circuit board 19 is disposed along a left side inner wall in a standing attitude within the sensor holder 6. Therefore, the area and the width dimension of the bottom face 55 of the head 5 where the magnetism-sensitive surface 50 is formed can be made smaller and narrower than those of the conventional head.

Accordingly, when the head 5 and the magnetic scale 3 are disposed as shown in FIG. 5, the bottom face 55 having the magnetism-sensitive surface 50 can be accurately faced to the magnetic scale 3. In other words, in the case that the head 5 and the magnetic scale 3 are disposed as shown in FIG. 5, first, the bottom face 55 of the head 5 is made to come in contact with the upper face of the magnetic scale 3 to determine its reference attitude and, after that, the head 5 is slightly lifted from the magnetic scale 3. Accordingly, in an embodiment of the present invention, since the area of the bottom face 55 is formed to be smaller and narrower, the reference attitude can be accurately determined because the entire bottom face 55 of the head 5 is sure to make contact with the upper face of the magnetic scale 3. As a result, a high degree of accuracy can be obtained in the attitude of the head 5 in the state that the head 5 is lifted from the magnetic scale 3.

Further, in accordance with an embodiment of the present invention, the reference surface 56 of the bottom face 55 of the head 5 where the magnetism-sensitive surface 50 is formed protrudes from its periphery by 0.2 mm-1.0 mm. The area of the same flat face as the magnetism-sensitive surface 50 is about half of that of the entire bottom face 55 and this area is small. Accordingly, in the case that the reference attitude is determined by the bottom face 55 of the head 5 bringing in contact with the upper face of the magnetic scale 3, the entire magnetism-sensitive surface 50 of the head 5 can be surely brought into contact with the upper face of the magnetic scale 3 because its contacting area is small. Therefore, the reference attitude can be determined accurately. As a result, the magnetism-sensitive surface 50 does not incline with respect to the magnetic scale 3 even in the state that the head 5 is lifted from the magnetic scale 3.

Since the bottom face 55 of the head 5 is used as the reference surface 56 of the magnetism-sensitive surface 50, machine working or the like is required to form the bottom face 55 precisely flat. However, in accordance with an embodiment of the present invention, only the center region of the bottom face of the head 5 having the magnetism-sensitive surface 50 is the reference surface 56. Therefore, the region required to perform machine working or the like is small and thus the production cost can be reduced because, for example, cutting work time is shortened.

In addition, the magnetism-sensitive surface 50 (reference surface 56) is protruded from the bottom face 55 of the sensor holder 6. Therefore, in the state that the head 5 is oppositely disposed to the magnetic scale 3, the magnetism-sensitive surface 50 can be confirmed by observing the clearance between the head 5 and the magnetic scale 3.

Further, in the magnetoresistive element 10 in accordance with an embodiment of the present invention, as described with reference to FIGS. 2(a) through 2(c), the first magnetoresistive element circuit board 11 and the second magnetoresistive element circuit board 12 are adhered to each other and the flexible circuit boards 16, 17 are connected to the respective protruding parts 115, 125 so as to be extended toward opposite sides. Moreover, since the flexible circuit boards 16, 17 are extended in a longitudinal direction (Y-direction) of the magnetic scale 3 from the magnetoresistive element 10, the flexible circuit boards 16, 17 can be also adhesively fixed to the sensor holder 6 even when the width dimension of the bottom face 55 of the sensor holder 6 is narrow. Therefore, since the magnetoresistive element 10 can be supported on both sides, the vibration resistant performance is superior. Further, the space of the periphery around the magnetoresistive element 10 in the opening part 57 is sealed with the adhesive 91 and thus the moisture resistant performance is also superior.

In addition, in the magnetoresistive element 10 in accordance with an embodiment of the present invention, the front face and the rear face of a pair of the flexible circuit boards 16, 17 are respectively connected to the first magnetoresistive element circuit board 11 and the second magnetoresistive element circuit board 12 in an opposite manner and thus the connection terminals 161, 171 of the flexible circuit boards 16, 17 are directed in reverse directions. However, in this embodiment of the present invention, the flexible circuit boards 16, 17 are bent and the flexible circuit board 16 is connected to the front face side of the circuit board 19 and the flexible circuit board 17 is connected to the rear face side of the circuit board 19. Therefore, flexible circuit boards of the same structure are reversibly used on the front and rear sides as a pair of the flexible circuit boards 16, 17. Accordingly, one type of flexible circuit board can be used for the flexible circuit boards 16, 17 and thus the cost can be reduced.

[Connecting Structure of Cable 7]

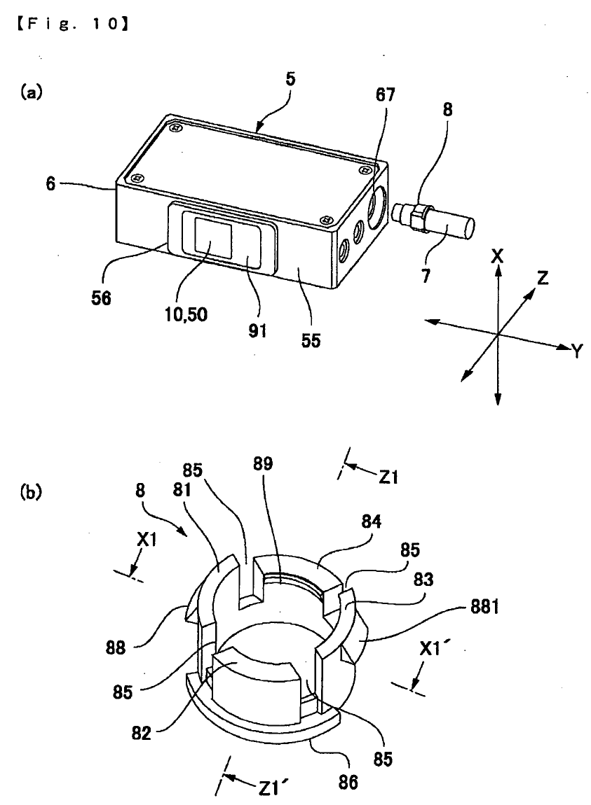

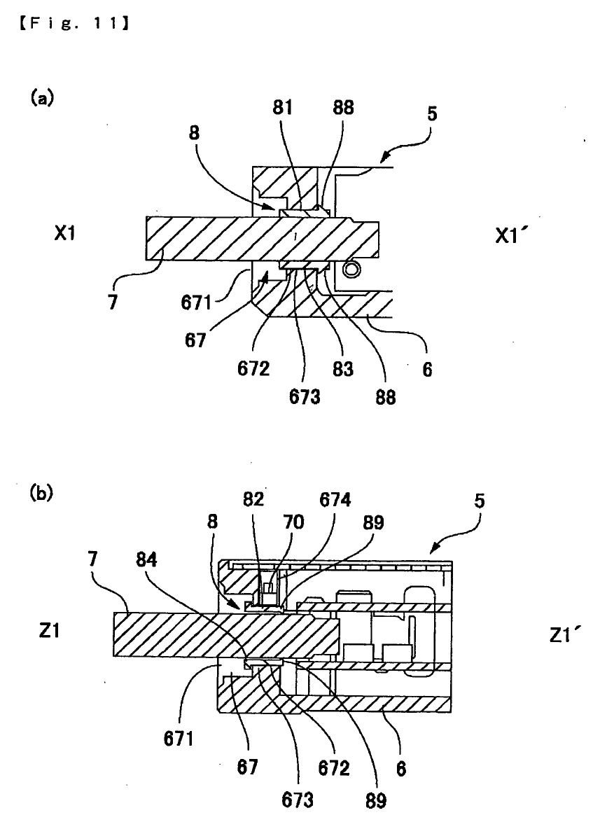

FIG. 10(a) is an explanatory view showing a connecting structure between the head 5 and the cable 7 which are used in the magnetic sensor device 1 in accordance with an embodiment of the present invention and FIG. 10(b) is a perspective view showing a sleeve used in the connecting structure shown in FIG. 10(a). FIG. 11(a) is a sectional view showing a portion around a cable insert hole which is cut at positions corresponding to the line X1-X1′ in FIG. 7(a) and FIG. 10(b) in order to show the state where the cable 7 is connected to the inside of the head 5 by using the sleeve shown in FIG. 10(b), and FIG. 11(b) is a sectional view showing a portion around the cable insert hole which is cut at positions corresponding to the line Z1-Z1′ in FIG. 7(b) and FIG. 10(b).

As shown in FIG. 10(a), in order to connect the cable 7 to the circuit board 19 within the head 5, a cable insert hole 67 for inserting the front end part of the cable 7 into the sensor holder 6 is formed in the back face of the sensor holder 6. The front end part of the cable 7 is inserted into the head 5 under the state that the cable 7 is passed through a sleeve 8 for slip-off prevention and the sleeve 8 is fitted into the cable insert hole 67.

The sleeve 8 is made of metal or resin and is provided with a cylindrical portion whose inner diameter is a little bigger than the outer diameter of the cable 7 as shown in FIG. 10(b). A ring-shaped flange portion 86 with a little larger diameter is formed on the base end side of the sleeve 8. The sleeve 8 is provided with four claw-shaped elastic piece parts 81, 82, 83, 84 which are formed by four slits 85 cut to its base end side from its front end side. The number of the elastic piece parts is not limited to four and may be two or more.

Two oppositely faced first elastic piece parts 81, 83 of four elastic piece parts 81, 82, 83, 84 are formed longer than the other second elastic plate parts 82, 84 and provided with first engaging projecting parts 88 on its outer face. The other two second elastic piece parts 82, 84 are provided with second engaging projecting parts 89 on its inner face and the tip end part of the second engaging projecting part 89 is brought into contact with the outer peripheral face of the cable 7 when the cable 7 is inserted through the sleeve 8.

On the other hand, as shown in FIGS. 11(a) and 11(b), a ring-shaped wall part 673 which forms an aperture part 672 smaller than an outer aperture part 671 is formed in the cable insert hole 67 of the sensor holder 6. Further, as shown in FIG. 11(b), a screw hole 674 which penetrates through the ring-shaped wall 673 to reach the aperture part 672 is formed in the cable insert hole 67 of the sensor holder 6.

Therefore, when the cable 7 is inserted into the cable insert hole 67 along with the sleeve 8 in the state that the cover 61 is detached from the sensor holder 6, the first engaging projecting parts 88 which are formed on the outer faces of the first elastic piece parts 81, 83 are respectively passed through the aperture part 672 and engage with an aperture edge on the inside of the ring-shaped wall 673. Accordingly, the sleeve 8 does not slip out from the cable insert hole 67. Further, when the screw 70 is fitted to the screw hole 674 formed in the ring-shaped wall 673 after the cable 7 has been inserted into the cable insert hole 67 along with the sleeve 8, the tip end part of the screw 70 causes the second elastic piece parts 82, 84 to deform elastically inside and causes the second engaging projecting parts 89 formed on the inner face of the second elastic piece parts 82, 84 to bite into the coating layer of cable 7. Accordingly, the cable 7 does not slip off from the cable insert hole 67. After that, the cover 61 is fitted to the sensor holder 6.

As described above, when the cable 7 is inserted into the cable insert hole 67 along with the sleeve 8, the extraction of the sleeve 8 is prevented by the first engaging projecting parts 88 and the extraction of the cable 7 is prevented by the second engaging projecting parts 89. Therefore, a sufficient pull-out force of the cable 7, for example, 29.4 N or more (3 kgf or more) can be secured. Further, since the sleeve 8 is formed of a single product, the extraction of the cable 7 can be prevented by the operations of only fitting to the cable 7, inserting into the cable insert hole 67, and fitting with a screw. Further, in accordance with an embodiment of the present invention, since a screw or the like is not formed in the sleeve 8, the sleeve 8 can be produced at a low cost.

Since the sensor holder 6 is provided with a hole 68 on its front face side which is formed in the same shape as the cable insert hole 67. Therefore, the cable 7 can be connected from either side of the front face and the back face of the sensor holder 6. When the hole 68 is not used, it is preferable that the sleeve 8 or another cap is fitted to this hole.

[Structure of Magnetic Scale 3]

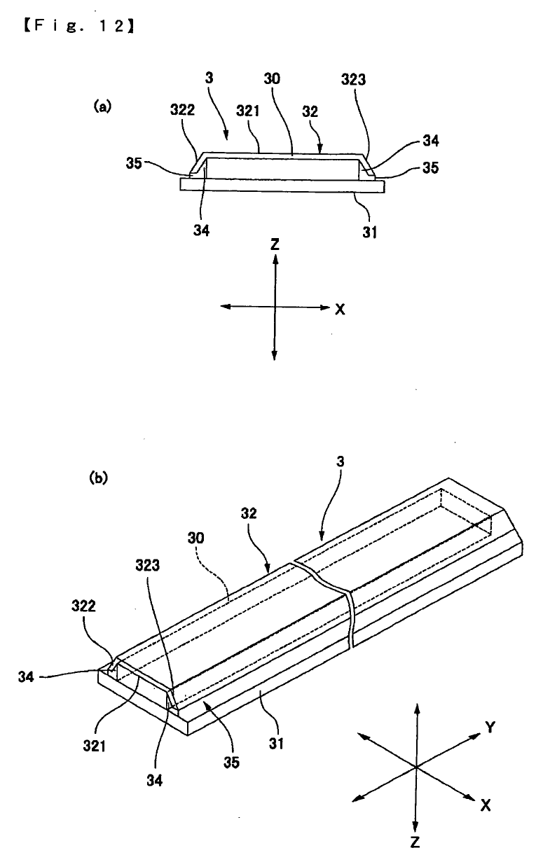

FIG. 12(a) is a longitudinal sectional view showing the magnetic scale 3 which is used in the magnetic sensor device 1 in accordance with an embodiment of the present invention and FIG. 12(b) is an explanatory view showing its internal structure.

As shown in FIGS. 12(a) and 12(b), the magnetic scale 3 which is used in the magnetic sensor device 1 in accordance with an embodiment of the present invention includes a flexible magnet 30 made of a rubber magnet or a plastic magnet in which magnetic poles are periodically formed in a longitudinal direction, a base plate 31 which is fixed on the rear face of the flexible magnet 30, and a protection plate 32 which is mounted on the front face of the flexible magnet 30. The flexible magnet 30 is a plastic magnet which is, for example, made of a base resin consisting of chlorinated polyethylene mixed with ferrite powder particles as a magnetic powder and is formed in a band shape having a constant width and the thickness of 1 mm. The base plate 31 is made of, for example, a cold rolled special steel strip or a cold-finished special band steel and is formed in a band shape with a constant width and the thickness of 0.5 mm. Metal plating processing for rust prevention such as chromate treatment is performed on the surface of the base plate 31.

The protection plate 32 is a thin plate made of SUS with the thickness of 50 μm. Both the right and left sides of the protection plate 32 are bent slantingly. Accordingly, the protection plate 32 is provided with an upper face part 321 which is parallel to the base plate 31 and slant face parts 322, 323 which are extended obliquely downward from the both sides. In an embodiment of the present invention, the slant face parts 322, 323 are bent at an angle of about 45° with respect to the upper face part 321.

In the case that the magnetic scale 3 is produced, after the flexible magnet 30 is fixed on the base plate 31 with a double-stick tape or the like, the flexible magnet 30 is magnetized. Next, the flexible magnet 30 is covered with the protection plate 32 whose side edge parts are bent at an angle of about 45°. Alternatively, after the flexible magnet 30 is covered with the protection plate 32 in a flat plate shape, the side edge parts of the protection plate 32 may be bent at an angle of about 45°. In this case, the width dimension of the protection plate 32 is set to be narrower than that of the base plate 31. Next, in the state that the flexible magnet 30 is covered with the base plate 31 and the protection plate 32, a gap space 35 is provided between the side edge part of the base plate 31 and the side edge part of the protection plate 32 and thus an adhesive 34 is injected into the inside through the gap space 35 and hardened. In an embodiment of the present invention, the adhesive 34 is a one-component, moisture-curable adhesive in which silyl group-containing special polymer is contained as a main component. The adhesive 34 reacts with a very small amount of moisture in air and cures. Further, since the adhesive 34 is provided with elasticity after curing, the stress relaxation properties for vibration, impact or the like are satisfactory. Therefore, a large stress is not applied to the flexible magnet 30.

As described above, in the magnetic scale 3 in accordance with an embodiment of invention, since the protection plate 32 whose right and left sides are obliquely bent is used, the magnetic scale 3 is not warped even when the magnetic scale 3 is longer than 1 m. Further, since the adhesive 34 has elasticity after having cured, the magnetic scale 3 is also effectively prevented from being warped due to the shrinkage of the adhesive 34. Further, since the flexible magnet 30 is completely sealed with the protection plate 32, the base plate 31 and the adhesive 34, the swelling of the flexible magnet 30 due to the adhering of lubricating oil to the flexible magnet 30 can be surely prevented. In addition, since the edge portions of the protection plate 32 are formed in a bent shape, a working personnel is not hurt by the edge portion of the protection plate.

While the description above refers to particular embodiments of the present invention, it will be understood that many modifications may be made without departing from the spirit thereof. The accompanying claims are intended to cover such modifications as would fall within the true scope and spirit of the present invention.

The presently disclosed embodiments are therefore to be considered in all respects as illustrative and not restrictive, the scope of the invention being indicated by the appended claims, rather than the foregoing description, and all changes which come within the meaning and range of equivalency of the claims are therefore intended to be embraced therein.

What is claimed is:

1. A magnetoresistive element comprising:
an A-phase magnetoresistive pattern which outputs a signal;
a B-phase magnetoresistive pattern which outputs another signal whose phase is different by 90° from a phase of the signal outputted from the A-phase magnetoresistive pattern;
a first substrate on which the A-phase magnetoresistive pattern is formed; and
a second substrate on which the B-phase magnetoresistive pattern is formed;
wherein at least one of the first and the second substrates is a transparent substrate.

2. The magnetoresistive element according to claim 1, wherein the first and the second substrates are disposed such that surfaces on which the A-phase and the B-phase magnetoresistive patterns are formed face each other.

3. The magnetoresistive element according to claim 2, further comprising a photosetting adhesive for adhesively fixing the first substrate and the second substrate to each other.

4. The magnetoresistive element according to claim 3, wherein the photosetting adhesive is a UV-curing adhesive.

5. The magnetoresistive element according to claim 2, wherein all of the A-phase and the B-phase magnetoresistive patterns formed on the first substrate and the second substrate are sandwiched between the first substrate and the second substrate.

6. The magnetoresistive element according to claim 5, wherein each of the first substrate and the second substrate protrudes from an edge part of the other substrate and respective protruding parts are connectable to a flexible circuit board.

7. The magnetoresistive element according to claim 1, wherein one of the first substrate and the second substrate is a transparent substrate and the other is a glazed ceramic substrate.

8. The magnetoresistive element according to claim 7, wherein the glazed ceramic substrate is disposed on a side which is to be faced with a magnetic scale that is to be detected by the A-phase and the B-phase magnetoresistive patterns and a thickness of the glazed ceramic substrate is thinner than a thickness of the transparent substrate.
